(19) United States
(12) Patent Application Publication
(10) Pub. No.: US 2026/0118408 A1
(43) Pub. Date: Apr. 30, 2026

(54) ENERGIZING TEST DEVICE

(71) Applicant: AKTIEBOLAGET SKF, GOTEBORG (SE)

(72) Inventors: Kai GU, Shanghai (CN); Liming MEI, Suzhou City (CN); Xuejun WEN, Shanghai (CN); Qin HAN, Shangai (CN); Yunlong FENG, Shanghai (CN)

(21) Appl. No.: 19/365,318

(22) Filed: Oct. 22, 2025

(30) Foreign Application Priority Data
Oct. 29, 2024 (CN) 202422611981.5

(51) Int. Cl. G01R 31/28; G01R 1/067

(52) U.S. Cl. CPC G01R 31/2839; G01R 1/06722; G01R 31/2844

(57) ABSTRACT

An energizing test device includes a support body having a shape and at least one test electrode mounted in the support body and configured to provide a test voltage to an electrical device under test. The electrical device under test includes a battery compartment configured to receive a battery pack, the battery compartment having a shape and having a voltage input terminal configured to introduce electric voltage into a working circuit of the electrical device under test. The support body is configured such that the support body is insertable into the battery compartment such that the at least one test electrode contacts the voltage input terminal. Also an assembly of the test device and the electrical device under test.

### CROSS-REFERENCE

This application claims priority to Chinese patent application no. 202422611981.5 filed on Oct. 29, 2024, the contents of which are fully incorporated herein by reference.

### TECHNOLOGICAL FIELD

The present disclosure relates to an energizing test device, especially an energizing test device that provides energizing test for a drive unit of a single-point lubricator.

### BACKGROUND

A Chinese utility model patent application No. 202422410159.2, titled “Intrinsically Safe Battery Assembly” filed by the applicant on Oct. 8, 2024 discloses a single-point lubricator that can automatically deliver a correct dose of a lubricant to a given lubrication point. As shown in FIGS. 1A, 1B, and 2 of the present application, this single-point lubricator comprises a drive unit 10 and a reservoir unit 20 that can be assembled together in a detachable manner. The drive unit 10 accommodates power components including an electric motor M and a battery pack 11 therein, and the reservoir unit 20 is used to store a lubricant (lubricant grease or lubricant oil). Generally, the battery pack 11 includes at least one battery, which fills in a battery compartment 1 in the working state. Utilizing the electric power provided by the battery pack 11, the electric motor M drives a pumping mechanism P to squeeze the lubricant in the reservoir unit 20 out of an oil outlet 21.

As shown more clearly in FIG. 2, the pumping mechanism P comprises a hydraulic cylinder formed by a cylindrical side wall 22 of the reservoir unit 20 and a piston 23 that forms a sliding sealing fit with the hydraulic cylinder (i.e., the cylindrical side wall 22). The electric motor M transmits output torque to a lead screw 25 through a rotating shaft 24, and then the lead screw 25 converts the torque of the electric motor into power for propelling the piston 23 along a straight line inside the reservoir unit 20 via a threaded fit with the piston 23. Based on the above power transmission, the electric motor M finally squeezes the lubricant in the reservoir unit 20 out of the oil outlet 21 below by utilizing the piston 23.

As a portion of detection content, the energizing detection of the power unit is conducted in the case that the battery compartment is empty (that is, the battery pack is not present) to detect the current distribution of the working circuit at test voltage and the frequency and strength (power) of a signal emitted by a wireless transmitting device. However, a voltage input terminal of the working circuit of the drive unit is typically designed to form an electrical connection with a voltage output terminal (usually comprising an output electrode of the battery) of the battery pack. In typical cases, they have smooth surfaces that are difficult to adhere to, and only form a reliable electrical connection with the voltage output terminal relying on assembly pressure after the battery pack is correctly assembled into the battery compartment. The above design of the voltage input terminal makes it quite difficult to manually introduce test voltage.

Reality calls for an energizing test device that can easily and conveniently direct the test voltage to a power input terminal.

### SUMMARY

To solve the technical problems described above, the present disclosure provides an energizing test device comprising test electrodes for providing a test voltage to an electrical device under test and a support portion for providing a structural support to the test electrodes. The electrical device under test is formed with a battery compartment for accommodating a battery pack and a voltage input terminal for introducing electric power into a working circuit of the electrical device under test. The battery pack is formed with its voltage output terminal configured to form a reliable electrical connection with the voltage input terminal after having been correctly assembled in the battery compartment. The test device is formed with a positioning mechanism for positioning the electrical device under test in a specific position, so that the electrical device under test, after being positioned, is just connected to the test electrodes of the energizing test device with its voltage input terminal.

The energizing test device can achieve an electrical connection between the electrical device under test and the test electrodes solely relying on the positioning mechanism, making it not only convenient to operate but also cost-effective, thus demonstrating great practical value.

### BRIEF DESCRIPTION OF THE DRAWINGS

Detailed embodiments of the present disclosure and beneficial technical effects thereof are described in detail below in conjunction with the accompanying drawings in which:

FIG. 1A is a sectional elevational view of a drive unit of a lubricator.

FIG. 1B is a sectional plan view of the drive unit of FIG. 1A.

FIG. 2 is a sectional elevational view of a reservoir unit connectable to the drive unit of FIG. 1A to form a single-point lubricator.

FIG. 3A is a front elevational view of an energizing test device according to the present disclosure that is usable with the drive unit of FIG. 1A.

FIG. 3B is a top plan view of the energizing test device of FIG. 3A.

FIG. 4 is an enlarged structural schematic view of a binding post.

FIG. 5 is a structural schematic view of the energizing test device of FIG. 3A connected to the drive unit of FIG. 1A.

### DETAILED DESCRIPTION

In the following description, identical or similar reference numerals are always used to denote the same or similar components. Terms indicating directions, for example, “axial”, “radial” and “circumferential (direction)”, each refer to the axial, radial and circumferential (direction) of the component being described, unless otherwise defined or specified.

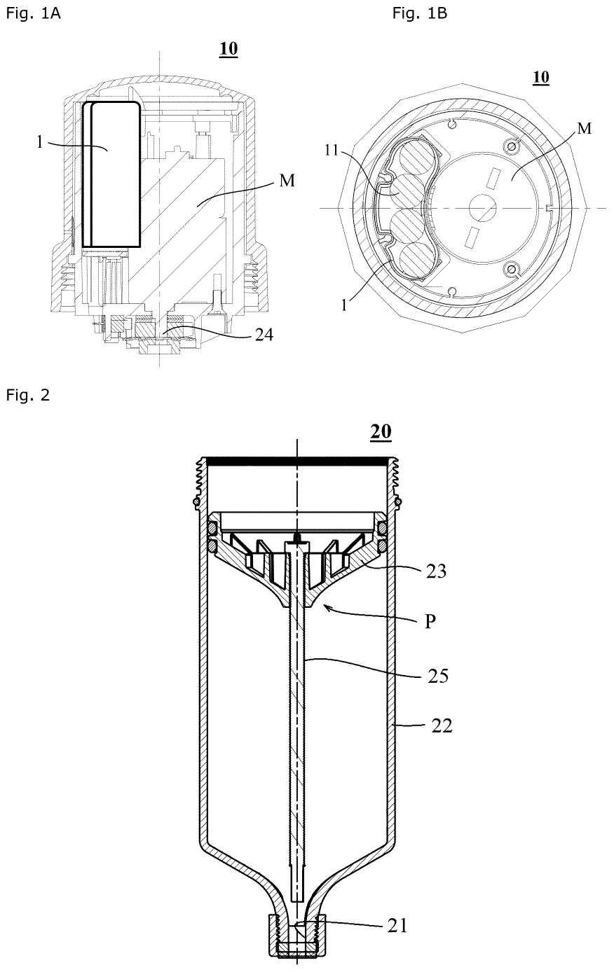

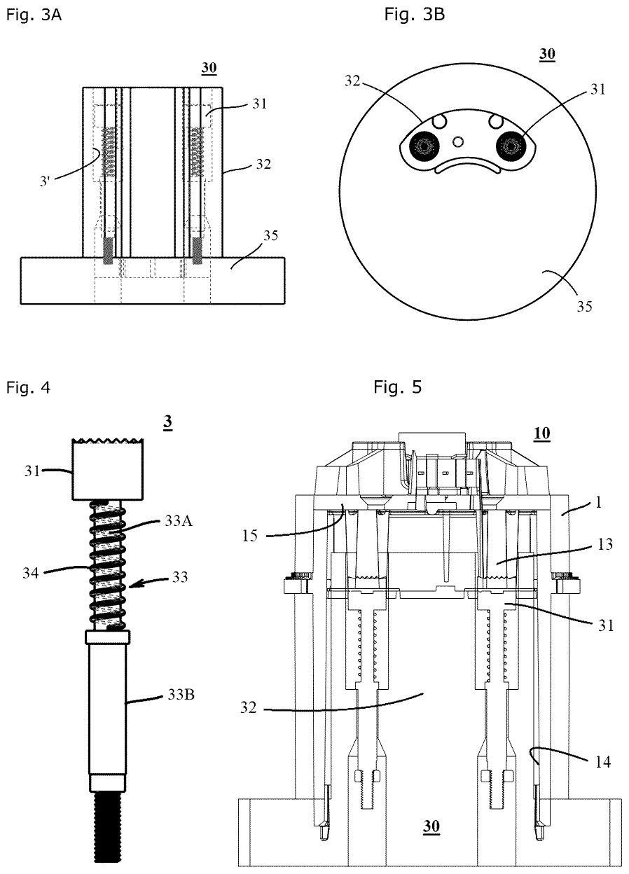

FIGS. 3A and 3B show structural schematic views of the energizing test device in different perspectives, respectively. It can be seen from the figures that, the test device 30 includes test electrodes 31 for providing a test voltage to an electrical device under test and a support portion 32 that structurally supports the test electrodes 31. As one preferred embodiment, the support portion 32 is formed to have at least a partial profile of a battery pack 11, for example, as shown in FIGS. 1B and 3B, have a generally circular arc-shaped cross-section, thereby enabling the positioning assembly of a drive unit 10 on the test device 30 by forming an embedded fit with a battery compartment 1.

FIG. 5 shows a structural schematic view of the drive unit and the test device forming the embedded fit. As shown in the figure, the battery compartment 1 has a compartment opening 14 for filling the battery pack 11 therein and a compartment bottom 15 opposite the compartment opening 14. When the support portion 32 is inserted into the battery compartment 1, the test electrodes 31 formed on the top of the support portion 32 will form an electrical connection with a voltage input terminal 13 (of the working circuit of the drive unit 10) formed in the compartment bottom 15 of the drive unit 10. In the example of the embedded fit shown in FIG. 5, the drive unit 10 is snapped on the top of the support portion 32 in a manner in which the compartment opening 14 of the battery compartment faces downward. This solution ensures a reliable electrical connection between the voltage input terminal 13 and the test electrodes 31 by utilizing the weight of the drive unit 10 itself.

In the embodiment shown in FIGS. 3A and 3B, the test voltage is directed to the test electrodes 31 through a binding post 3, the binding post 3 is assembled in an internal channel 3′ of the support portion 32. FIG. 4 shows an enlarged structural view of the binding post. It can be seen from the figure that, the binding post 3 is formed with a resilient telescopic portion 33, comprising a rod 33A and a sleeve 33B having a sliding nesting relationship with each other. Wherein, the rod 33A has one end forming a head with a larger diameter and the other end forming a neck with a smaller diameter. The head forms or supports the test electrodes 31, the neck is used to insert into an inner hole of the sleeve 33B.

In the design described above, the rod 33A and the sleeve 33B form a resilient telescopic portion 33 by a support of a spring 34. Specifically, the spring 34 is fitted on the periphery of the neck of the rod 33A, with an upper end supporting the head of the rod 33A and a lower end supporting an upper end face of the sleeve 33B, and the sleeve 33B forms a fixed connection with a base 35 of the test device 30 in a manner of bolt fastening or bonding. The resilient telescopic portion 33 can provide a resilient force to press the test electrodes 31 against the voltage input terminal 13 by telescopic deformation, under the gravitational force of the drive unit 30.

In the embodiment described above, a wire (not shown) may be utilized to sequentially pass through the sleeve 33B and the rod 33A, for example, directing the program-controlled test voltage to the electrodes 31 on the top of the binding post 3. As one preferred embodiment, the rod 33A and the sleeve 33B may also be made of metallic materials (for example, copper, aluminum, etc.), forming a series circuit together with the metallic spring 34, thereby conducting the test voltage to the test electrodes 31.

In the embodiment described above, the embedded fit between the support portion 32 and the battery compartment 1 is used for positioning, enabling the drive unit 10 to connect to the test electrodes 31 of the test device 30 with its voltage input terminal 13. In the positioning process described above, the support portion 32 not only provides the structural support to the test electrodes 31, but also acts as a positioning mechanism that secures the drive unit 10 on the test device 30. However, the positioning mechanism may also be implemented by employing other mechanisms (for example, a snap mechanism, a magnetic mechanism, etc.). It can be seen that, the implementation of the present disclosure does not take “support portion itself forming the positioning mechanism” as a requisite. In a broad sense, any form of positioning mechanism can achieve the purpose of the present disclosure as long as it can achieve the positioning of the drive unit on the test device and ensure that the drive unit, after being positioned, automatically achieve the reliable electrical connection with the test device.

Once the electrical connection is formed between the test electrodes and the voltage input terminal, the test device may perform tests on the drive unit. The tests include detecting the current in the working circuit at a predetermined test voltage, and also include detecting the frequency and/or strength of the signal emitted by a radio signal transmitting device inside the drive unit under the same conditions.

The above describes various detailed embodiments of the energizing test device of the present disclosure using the drive unit of a lubricator as an example. It is not difficult to understand that, the disclosure concept of synchronously achieving the electrical connection between the drive unit and the testing device through the mechanical positioning therebetween is also applicable to other types of electrical devices under test, including but not limited to electrical devices provided with the battery compartment. In the latter case, the positioning mechanism may achieve the above purpose by the embedded fit with the battery compartment that is unoccupied. Therefore, the present disclosure is applicable not only to the drive unit of the lubricator but also to any other type of electrical devices under test.

The energizing test device described above is not limited by the specific embodiments and more general technical solutions will be subject to the limitations of the accompanying claims. Any modifications and improvements to the present disclosure are within the scope of protection of the present disclosure, provided they conform to the limitations of the accompanying claims.

What is claimed is:

1. An energizing test device comprising:
a support body having a shape,
at least one test electrode mounted in the support body and being configured to provide a test voltage to an electrical device under test,
wherein the electrical device under test includes a battery compartment configured to receive a battery pack, the battery compartment having a shape and a voltage input terminal configured to introduce electric voltage into a working circuit of the electrical device under test, and
wherein the support body is configured such that the support body is insertable into the battery compartment such that the at least one test electrode contacts the voltage input terminal.

2. The energizing test device according to claim 1,
including a current detector for detecting a current in a working circuit of the electrical device under test.

3. The energizing test device according to claim 1,
including a wireless signal detector for detecting a frequency and/or a strength of a wireless signal produced by the electrical device under test.

4. An assembly comprising:
the energizing test device according to claim 2, and
the electrical device under test,
wherein the shape of the support body at least partially complementary to the shape of the battery compartment.

5. The assembly according to claim 4,
wherein the battery compartment has an opening configured to receive the battery pack and a bottom wall opposite the opening,
wherein the voltage input terminal is located on the bottom wall,
wherein the at least one test electrode is formed on a top wall of the support body, and
wherein, the top wall of the support body faces the bottom wall of the battery compartment when the support body is inserted in the battery compartment.

6. The assembly according to claim 5,
wherein the support body is configured such that a weight of the electrical device under test holds the voltage input terminal in electrical contact with the at least one test electrode.

7. The assembly according to claim 6,
wherein the at least one test electrode is mounted on a spring-biased binding post.

8. The assembly according to claim 7,
wherein the binding post comprises a rod telescopically mounted in a sleeve and a spring configured to bias the rod in a direction out of the sleeve.

9. The assembly according to claim 5,
wherein the electrical device under test is a drive unit of a single-point lubricator.

10. An assembly comprising:
the energizing test device according to claim 3, and
the electrical device under test,
wherein the shape of the support body at least partially complementary to the shape of the battery compartment.

11. The assembly according to claim 10,
wherein the battery compartment has an opening configured to receive the battery pack and a bottom wall opposite the opening,
wherein the voltage input terminal is located on the bottom wall,
wherein the at least one test electrode is formed on a top wall of the support body, and
wherein, the top wall of the support body faces the bottom wall of the battery compartment when the support body is inserted in the battery compartment.

12. The assembly according to claim 11,
wherein the support body is configured such that a weight of the electrical device under test holds the voltage input terminal in electrical contact with the at least one test electrode.

13. The assembly according to claim 12,
wherein the at least one test electrode is mounted on a spring-biased binding post.

14. The assembly according to claim 13,
wherein the binding post comprises a rod telescopically mounted in a sleeve and a spring configured to bias the rod in a direction out of the sleeve.

15. The assembly according to claim 14,
wherein the electrical device under test is a drive unit of a single-point lubricator.
